(19) United States
(12) Patent Application Publication
(10) Pub. No.: US 2015/0263508 A1
(43) Pub. Date: Sep. 17, 2015

(54) SYSTEM AND METHOD FOR DETECTING ISLANDING OF ELECTRICAL MACHINES AND PROTECTING SAME

(71) Applicants: Huibin Zhu, Schenectady, NY (US); Allen Michael Ritter, Salem, VA (US); Einar Vaughn Larsen, Schenectady, NY (US); Anthony Michael Klodowski, Salem, VA (US); Sidney Allen Barker, Salem, VA (US); Xueqin Wu, Shanghai (CN); Shouzhong Chang, Shanghai (CN)

(72) Inventors: Huibin Zhu, Schenectady, NY (US); Allen Michael Ritter, Salem, VA (US); Einar Vaughn Larsen, Schenectady, NY (US); Anthony Michael Klodowski, Salem, VA (US); Sidney Allen Barker, Salem, VA (US); Xueqin Wu, Shanghai (CN); Shouzhong Chang, Shanghai (CN)

(21) Appl. No.: 14/423,443

(22) PCT Filed: Aug. 30, 2012
(86) PCT No.: PCT/CN2012/080763

§ 371 Date: Feb. 24, 2015

(51) Int. Cl. H02H 7/06; G01R 21/00; F03D 11/00; G01R 19/165; F03D 9/00; H02J 3/38; G01R 25/00

(52) U.S. Cl. CPC H02H 7/06; H02J 3/38; G01R 21/00; G01R 25/00; G01R 19/165; F03D 9/003; F03D 11/0091; H02J 2003/388

(57) ABSTRACT

In one aspect, a method for protecting one or more electrical machines during an islanding event is provided. The method includes connecting one or more electrical machines to an alternating current (AC) electric power system, wherein the AC electric power system is configured to transmit at least one phase of electrical power to the one or more electrical machines or to receive at least on phase of electrical power from the one or more electrical machines; electrically coupling at least a portion of a control system to at least a portion of the AC electric power system; coupling at least a portion of the control system in electronic data communication with at least a portion of the one or more electrical machines; and detecting an islanding of the one or more electrical machines based on one or more conditions monitored by the control system.

### FIELD OF THE INVENTION

The present subject matter relates generally to electrical machines and, more particularly, to a system and method for detecting islanding events of one or more sources of electrical generation and protecting the one or more sources of electrical generation during the islanding event.

### BACKGROUND OF THE INVENTION

Generally, a wind turbine generator includes a turbine that has a rotor that includes a rotatable hub assembly having multiple blades. The blades transform mechanical wind energy into a mechanical rotational torque that drives one or more generators via the rotor. The generators are generally, but not always, rotationally coupled to the rotor through a gearbox. The gearbox steps up the inherently low rotational speed of the rotor for the generator to efficiently convert the rotational mechanical energy to electrical energy, which is fed into a utility grid via at least one electrical connection. Gearless direct drive wind turbine generators also exist. The rotor, generator, gearbox and other components are typically mounted within a housing, or nacelle, that is positioned on top of a base that may be a truss or tubular tower.

Some wind turbine generator configurations include doubly fed induction generators (DFIGs). Such configurations may also include power converters that are used to transmit generator excitation power to a wound generator rotor from one of the connections to the electric utility grid connection. Moreover, such converters, in conjunction with the DFIG, also transmit electric power between the utility grid and the generator as well as transmit generator excitation power to a wound generator rotor from one of the connections to the electric utility grid connection. Alternatively, some wind turbine configurations include, but are not limited to, alternative types of induction generators, permanent magnet (PM) synchronous generators and electrically-excited synchronous generators and switched reluctance generators. These alternative configurations may also include power converters that are used to convert the frequencies as described above and transmit electrical power between the utility grid and the generator. In some instances, sources of electrical generation such as the wind turbine generators described above may be located in remote areas far from the loads they serve. Typically, these sources of generation are connected to the electrical grid through an electrical system such as long transmission lines. These transmission lines are connected to the grid using one or more breakers. Islanding of these electrical machines by sudden tripping of the transmission line breaker at the grid side or otherwise opening these transmission lines while the source of generation is under heavy load may result in an overvoltage on the transmission line that can lead to damage to the source of generation or equipment associated with the source of generation such as converters and inverters.

Accordingly, an improved system and/or method that provides for detection of an islanding event to one or more electrical machines that allows time for protective action to be taken to prevent damaging the sources of generation and equipment associated with the sources of generation would be welcomed in the technology.

### BRIEF DESCRIPTION OF THE INVENTION

In one aspect, a method for an islanding event of one or more electrical machines is provided. The method includes (a) receiving a first indicator of an islanding of one or more electrical machines; (b) determining, by a computing device, whether the received first indicator is determinative of islanding of the one or more electrical machines; (c) if the computing device determines that the received first indicator is determinative of islanding of the one or more electrical machines, then sending one or more signals by the computing device to protect the one or more electrical machines; (d) if the computing device determines that the received first indicator is not determinative of islanding of the one or more electrical machines, then receiving one or more additional condition indicators; (e) determining, by the computing device, whether the one or more additional condition indicators are determinative of islanding of the one or more electrical machines; (f) if the computing device determines that the one or more additional condition indicators are determinative of islanding of the one or more electrical machines, then sending the one or more signals by the computing device to protect at least a portion of the one or more electrical machines; and (g) if the computing device determines that the one or more additional condition indicators are not determinative of islanding of the one or more electrical machines, then repeating steps (a) through (g).

In another aspect, another method for detecting an islanding event of one or more electrical machines is provided. The method includes connecting one or more electrical machines to an alternating current (AC) electric power system, wherein the AC electric power system is configured to transmit at least one phase of electrical power to the one or more electrical machines or to receive at least on phase of electrical power from the one or more electrical machines; electrically coupling at least a portion of a control system to at least a portion of the AC electric power system; coupling at least a portion of the control system in electronic data communication with at least a portion of the one or more electrical machines; and detecting an islanding of the one or more electrical machines based on one or more conditions monitored by the control system, said detecting comprising: (a) receiving a first indicator of an islanding of the one or more electrical machines; (b) determining, by the control system, whether said received first indicator is determinative of islanding; (c) if the control system determines that the received first indicator is determinative of islanding, then sending one or more signals by the control system to protect the one or more electrical machines; (d) if the control system determines that the received first indicator is not determinative of islanding, then receiving one or more additional condition indicators; (e) determining, by the control system, whether the one or more additional condition indicators are determinative of islanding; and (f) if the control system determines that the one or more additional condition indicators are determinative of islanding, then sending the one or more signals by the control system to protect at least a portion of the one or more electrical machines.

In yet another aspect, a system for detecting an islanding event of one or more electrical machines is provided. The system includes one or more electri cal machines connected to an alternating current (AC) electric power system, wherein the AC electric power system is configured to transmit at least one phase of electrical power to the one or more electrical machines or to receive at least on phase of electrical power from the one or more electrical machines; a control system, wherein the control system is electrically coupled to at least a portion of the AC electric power system and at least a portion of the control system is coupled in electronic data communication with at least a portion of the one or more electrical machines, and wherein the control system comprises a controller and the controller is configured to: (a) receive a first indicator of an islanding of the one or more electrical machines; (b) determine whether the received first indicator is determinative of islanding of the one or more electrical machines; (c) if the controller determines that the received first indicator is determinative of islanding of the one or more electrical machines, then sending one or more signals to protect the one or more electrical machines; (d) if the controller determines that the received first indicator is not determinative of islanding of the one or more electrical machines, then receiving one or more additional condition indicators; (e) determine whether the one or more additional condition indicators are determinative of islanding of the one or more electrical machines; (f) if the controller determines that the one or more additional condition indicators are determinative of islanding of the one or more electrical machines, then sending the one or more signals to protect at least a portion of the one or more electrical machines; and (g) if the controller determines that the one or more additional condition indicators are not determinative of islanding of the one or more electrical machines, then repeating steps (a) through (g).

These and other features, aspects and advantages of the present invention will become better understood with reference to the following description and appended claims. The accompanying drawings, which are incorporated in and constitute a part of this specification, illustrate embodiments of the invention and, together with the description, serve to explain the principles of the invent ion.

### BRIEF DESCRIPTION OF THE DRAWINGS

A full and enabling disclosure of embodiments of the present invention, including the best mode thereof, directed to one of ordinary skill in the art, is set forth in the specification, which makes reference to the appended figures, in which:

FIG. 1 is a schematic view of an exemplary wind turbine generator;

FIG. 2 is a schematic view of an exemplary electrical and control system that may be used with the wind turbine generator shown in FIG. 1;

FIG. 3 illustrates a block diagram of one embodiment of suitable components that may be included within an embodiment of a controller, or any other computing device that receives signals indicating islanding conditions in accordance with aspects of the present subject matter; and

FIG. 4 is flowchart illustrating an embodiment of a method of detecting an islanding of one or more electrical machines such as wind turbine generators.

### DETAILED DESCRIPTION OF THE INVENTION

Before the present methods and systems are disclosed and described, it is to be understood that the methods and systems are not limited to specific synthetic methods, specific components, or to particular compositions. It is also to be understood that the terminology used herein is for describing particular embodiments only and is not intended to be limiting.

As used in the specification and the appended claims, the singular forms ³D,′ ³DQ′ DQG ³WKH′ LQF0XGH SOXUD0 UHIHUHQWV XQ0HVV WKH FRQWH[W F0HDUO\ GLFWDWHV otherwise. Ranges may be expressed heUHLQ DV IURP ³DERXW′ RQH SDUWLFX0DU YD0XH, DQG/RU WR ³DERXW′ DQRWKHU SDUWLFX0DU YD0XH. =KHQ VXFK D UDQJH LV H[SUHVVHG, DQRWKHU embodiment includes from the one particular value and/or to the other particular value. Similarly, when values are expressed as approximations, by use of the antecedent ³DERXW,′ LW ZL00 EH XQGHUVWRRG WKDW WKH SDUWLFX0DU YD0XH IRUPV DQRWKHU HPERGLPHQW. ,W will be further understood that the endpoints of each of the ranges are significant both in relation to the other endpoint, and independently of the other endpoint.

³2SWLRQD0′ RU ³RSWLRQD00\′ PHDQV WKDW WKH VXEVHTXHQW0\ GHVFULEHG HYHQW RU circumstance may or may not occur, and that the description includes instances where said event or circumstance occurs and instances where it does not.

Throughout the description and claims of this specification, the word ³FRPSULVH′ DQG YDULDWLRQV RI WKH ZRUG, VXFK DV ³FRPSULVLQJ′ DQG ³FRPSULVHV,′ PHDQV ³LQF0XGLQJ EXW QRW 0LPLWHG WR,′ DQG LV QRW LQWHQGHG WR H[F0XGH, IRU H[DPS0H, RWKHU additives, FRPSRQHQWV, LQWHJHUV RU VWHSV. ³([HPS0DU\′ PHDQV ³DQ H[DPS0H RI′ DQG LV QRW LQWHQGHG WR FRQYH\ DQ LQGLFDWLRQ RI D SUHIHUUHG RU LGHD0 HPERGLPHQW. ³6XFK DV′ LV not used in a restrictive sense, but for explanatory purposes.

Disclosed are components that can be used to perform the disclosed methods and systems. These and other components are disclosed herein, and it is understood that when combinations, subsets, interactions, groups, etc. of these components are disclosed that while specific reference of each various individual and collective combinations and permutation of these may not be explicitly disclosed, each is specifically contemplated and described herein, for all methods and systems. This applies to all aspects of this application including, but not limited to, steps in disclosed methods. Thus, if there are a variety of additional steps that can be performed it is understood that each of these additional steps can be performed with any specific embodiment or combination of embodiments of the disclosed methods.

The present methods and systems may be understood more readily by reference to the following detailed description of preferred embodiments and the Examples included therein and to the Figures and their previous and following description.

Generally disclosed herein are systems and methods of detecting islanding of one or more electrical machines. Such electrical machines can include, for example, electric motors, electric generators including, for example, wind turbine generators, solar/photovoltaic generation, and the like, and any ancillary equipment associated with such electric machines. In one aspect, embodiments of the present invention disclose systems and methods to rapidly detect islanding of one or more wind turbine generators and taking actions to protect the one or more wind turbine generators and any ancillary equipment from electrical transients caused by the islanding event.

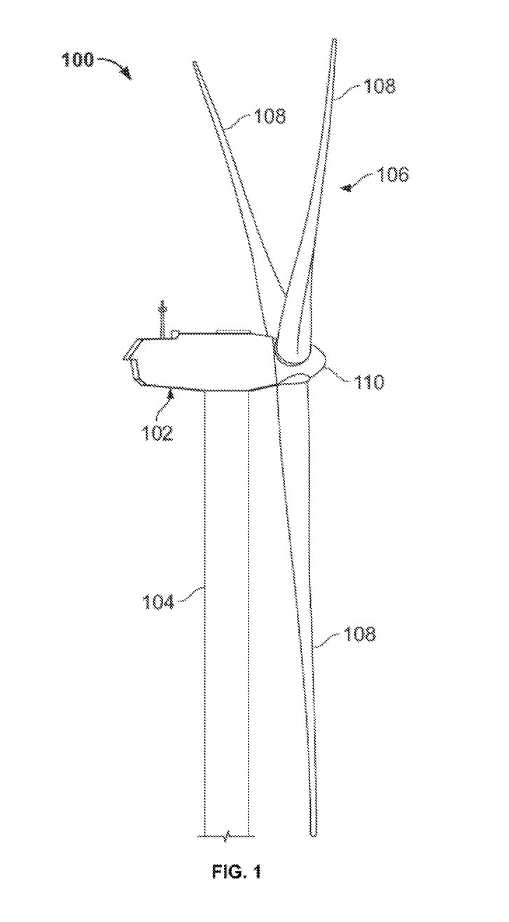

FIG. 1 is a schematic view of an exemplary wind turbine generator 100. The wind turbine 100 includes a nacelle 102 housing a generator (not shown in FIG. 1). Nacelle 102 is mounted on a tower 104 (a portion of tower 104 being shown in FIG. 1). Tower 104 may be any height that facilitates operation of wind turbine 100 as described herein. Wind turbine 100 also includes a rotor 106 that includes three rotor blades 108 attached to a rotating hub 110. Alternatively, wind turbine 100 includes any number of blades 108 that facilitate operation of wind turbine 100 as described herein. In the exemplary embodiment, wind turbine 100 includes a gearbox (not shown in FIG. 1) rotatingly coupled to rotor 106 and a generator (not shown in FIG. 1).

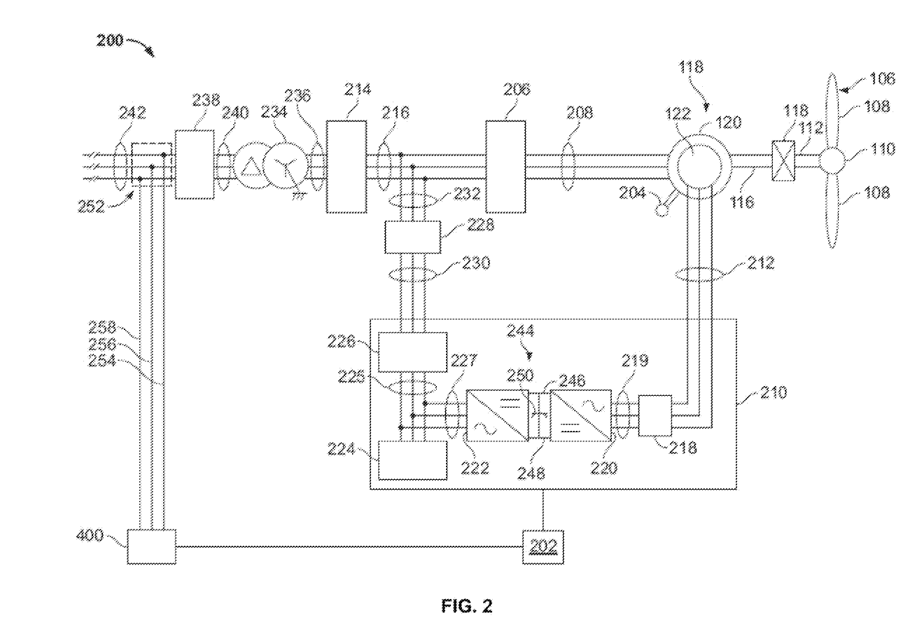

FIG. 2 is a schematic view of an exemplary electrical and control system 200 that may be used with wind turbine generator 100 (shown in FIG. 1). Rotor 106 includes plurality of rotor blades 108 coupled to rotating hub 110. Rotor 106 also includes a low-speed shaft 112 rotatably coupled to hub 110. Low-speed shaft is coupled to a step-up gearbox 114. Gearbox 114 is configured to step up the rotational speed of low-speed shaft 112 and transfer that speed to a high-speed shaft 116. In the exemplary embodiment, gearbox 114 has a step-up ratio of approximately 70:1. For example, low-speed shaft 112 rotating at approximately 20 revolutions per minute (20) coupled to gearbox 114 with an approximately 70:1 step-up ratio generates a high-speed shaft 116 speed of approximately 1400 rpm. Alternatively, gearbox 114 has any step-up ratio that facilitates operation of wind turbine 100 as described herein. Also, alternatively, wind turbine 100 includes a direct-drive generator wherein a generator rotor (not shown in FIG. 1) is rotatingly coupled to rotor 106 without any intervening gearbox.

High-speed shaft 116 is rotatably coupled to generator 118. In the exemplary embodiment, generator 118 is a wound rotor, synchronous, 60 Hz, three-phase, doubly-fed induction generator (DFIG) that includes a generator stator 120 magnetically coupled to a generator rotor 122. Alternatively, generator 118 is any generator that facilitates operation of wind turbine 100 as described herein.

Electrical and control system 200 includes a controller 202. Controller 202 includes at least one processor and a memory, at least one processor input channel, at least one processor output channel, and may include at least one computer (none shown in FIG. 2). As used herein, the term computer is not limited to just those integrated circuits referred to in the art as a computer, but broadly refers to a processor, a microcontroller, a microcomputer, a programmable logic controller (PLC), an application specific integrated circuit, and other programmable circuits (none shown in FIG. 2), and these terms are used interchangeably herein. In the exemplary embodiment, memory may include, but is not limited to, a computer-readable medium, such as a random access memory (RAM) (none shown in FIG. 2). Alternatively, a floppy disk, a compact disc±read only memory (CD-ROM), a magneto-optical disk (MOD), and/or a digital versatile disc (DVD) (none shown in FIG. 2) may also be used. Also, in the exemplary embodiment, additional input channels (not shown in FIG. 2) may be, but not be limited to, computer peripherals associated with an operator interface such as a mouse and a keyboard (neither shown in FIG. 2). Alternatively, other computer peripherals may also be used that may include, for example, but not be limited to, a scanner (not shown in FIG. 2). Furthermore, in the exemplary embodiment, additional output channels may include, but not be limited to, an operator interface monitor (not shown in FIG. 2).

Processors for controller 202 process information transmitted from a plurality of electrical and electronic devices that may include, but not be limited to, speed and power transducers. RAM and storage device store and transfer information and instructions to be executed by the processor. RAM and storage devices can also be used to store and provide temporary variables, static (i.e., non-changing) information and instructions, or other intermediate information to the processors during execution of instructions by the processors. Instructions that are executed include, but are not limited to, resident conversion and/or comparator algorithms. The execution of sequences of instructions is not limited to any specific combination of hardware circuitry and software instructions.

Electrical and control system 200 also includes generator rotor tachometer 204 that is coupled in electronic data communication with generator 118 and controller 202. Generator stator 120 is electrically coupled to a stator synchronizing switch 206 via a stator bus 208. In the exemplary embodiment, to facilitate the DFIG configuration, generator rotor 122 is electrically coupled to a bi-directional power conversion assembly 210 via a rotor bus 212. Alternatively, system 200 is configured as a full power conversion system (not shown) known in the art, wherein a full power conversion assembly (not shown) that is similar in design and operation to assembly 210 is electrically coupled to stator 120 and such full power conversion assembly facilitates channeling electrical power between stator 120 and an electric power transmission and distribution grid (not shown). Stator bus 208 transmits three-phase power from stator 120 and rotor bus 212 transmits three-phase power from rotor 122 to assembly 210. Stator synchronizing switch 206 is electrically coupled to a main transformer circuit breaker 214 via a system bus 216.

Assembly 210 includes a rotor filter 218 that is electrically coupled to rotor 122 via rotor bus 212. Rotor filter 218 is electrically coupled to a rotor-side, bi-directional power converter 220 via a rotor filter bus 219. Converter 220 is electrically coupled to a line-side, bi-directional power converter 222. Converters 220 and 222 are substantially identical. Power converter 222 is electrically coupled to a line filter 224 and a line contactor 226 via a line-side power converter bus 223 and a line bus 225. In the exemplary embodiment, converters 220 and 222 are configured in a three-phase, pulse width modulation (PWM) configuration including insulated gate ELSR0DU WUDQVLNNRU (,*%7) VZWFKLQJ GHYLFHV (QRW VKRZQ LQ)LJXUH 2) KD ³ILUH′ DV LV known in the art. Alternatively, converters 220 and 222 have any configuration using any switching devices that facilitate operation of system 200 as described herein. Assembly 210 is coupled in electronic data communication with controller 202 to control the operation of converters 220 and 222.

Line contactor 226 is electrically coupled to a conversion circuit breaker 228 via a conversion circuit breaker bus 230. Circuit breaker 228 is also electrically coupled to system circuit breaker 214 via system bus 216 and connection bus 232. System circuit breaker 214 is electrically coupled to an electric power main transformer 234 via a generator-side bus 236. Main transformer 234 is electrically coupled to a grid circuit breaker 238 via a breaker-side bus 240. Grid breaker 238 is connected to an electric power transmission and distribution grid via a grid bus 242.

In the exemplary embodiment, converters 220 and 222 are coupled in electrical communication with each other via a single direct current (DC) link 244. Alternatively, converters 220 and 222 are electrically coupled via individual and separate DC links (not shown in FIG. 2). DC link 244 includes a positive rail 246, a negative rail 248, and at least one capacitor 250 coupled therebetween. Alternatively, capacitor 250 is one or more capacitors configured in series or in parallel between rails 246 and 248.

System 200 further includes a phase-locked loop (PLL) regulator 400 that is configured to receive a plurality of voltage measurement signals from a plurality of voltage transducers 252. In the exemplary embodiment, each of three voltage transducers 252 are electrically coupled to each one of the three phases of bus 242. Alternatively, voltage transducers 252 are electrically coupled to system bus 216. Also, alternatively, voltage transducers 252 are electrically coupled to any portion of system 200 that facilitates operation of system 200 as described herein. PLL regulator 400 is coupled in electronic data communication with controller 202 and voltage transducers 252 via a plurality of electrical conduits 254, 256, and 258. Alternatively, PLL regulator 400 is configured to receive any number of voltage measurement signals from any number of voltage transducers 252, including, but not limited to, one voltage measurement signal from one voltage transducer 252. Controller 202 can also receive any number of current feedbacks from current transformers or current transducers that are electrically coupled to any portion of system 200 that facilitates operation of system 200 as described herein such as, for example, stator current feedback from stator bus 208, grid current feedback from generator side bus 236, and the like.

During operation, wind impacts blades 108 and blades 108 transform mechanical wind energy into a mechanical rotational torque that rotatingly drives low-speed shaft 112 via hub 110. Low-speed shaft 112 drives gearbox 114 that subsequently steps up the low rotational speed of shaft 112 to drive high-speed shaft 116 at an increased rotational speed. High speed shaft 116 rotatingly drives rotor 122. A rotating magnetic field is induced within rotor 122 and a voltage is induced within stator 120 that is magnetically coupled to rotor 122. Generator 118 converts the rotational mechanical energy to a sinusoidal, three-phase alternating current (AC) electrical energy signal in stator 120. The associated electrical power is transmitted to main transformer 234 via bus 208, switch 206, bus 216, breaker 214 and bus 236. Main transformer 234 steps up the voltage amplitude of the electrical power and the transformed electrical power is further transmitted to a grid via bus 240, circuit breaker 238 and bus 242.

In the doubly-fed induction generator configuration, a second electrical power transmission path is provided. Electrical, three-phase, sinusoidal, AC power is generated within wound rotor 122 and is transmitted to assembly 210 via bus 212. Within assembly 210, the electrical power is transmitted to rotor filter 218 wherein the electrical power is modified for the rate of change of the PWM signals associated with converter 220. Converter 220 acts as a rectifier and rectifies the sinusoidal, three-phase AC power to DC power. The DC power is transmitted into DC link 244. Capacitor 250 facilitates mitigating DC link 244 voltage amplitude variations by facilitating mitigation of a DC ripple associated with AC rectification.

The DC power is subsequently transmitted from DC link 244 to power converter 222 wherein converter 222 acts as an inverter configured to convert the DC electrical power from DC link 244 to three-phase, sinusoidal AC electrical power with pre-determined voltages, currents, and frequencies. This conversion is monitored and controlled via controller 202. The converted AC power is transmitted from converter 222 to bus 216 via buses 227 and 225, line contactor 226, bus 230, circuit breaker 228, and bus 232. Line filter 224 compensates or adjusts for harmonic currents in the electric power transmitted from converter 222. Stator synchronizing switch 206 is configured to close such that connecting the three-phase power from stator 120 with the three-phase power from assembly 210 is facilitated.

Circuit breakers 228, 214, and 238 are configured to disconnect corresponding buses, for example, when current flow is excessive and can damage the components of the system 200. Additional protection components are also provided, including line contactor 226, which may be controlled to form a disconnect by opening a switch (not shown in FIG. 2) corresponding to each of the lines of the line bus 230.

Assembly 210 compensates or adjusts the frequency of the three-phase power from rotor 122 for changes, for example, in the wind speed at hub 110 and blades 108. Therefore, in this manner, mechanical and electrical rotor frequencies are decoupled and the electrical stator and rotor frequency matching is facilitated substantially independently of the mechanical rotor speed.

Under some conditions, the bi-directional characteristics of assembly 210, and specifically, the bi-directional characteristics of converters 220 and 222, facilitate feeding back at least some of the generated electrical power into generator rotor 122. More specifically, electrical power is transmitted from bus 216 to bus 232 and subsequently through circuit breaker 228 and bus 230 into assembly 210. Within assembly 210, the electrical power is transmitted through line contactor 226 and busses 225 and 227 into power converter 222. Converter 222 acts as a rectifier and rectifies the sinusoidal, three-phase AC power to DC power. The DC power is transmitted into DC link 244. Capacitor 250 facilitates mitigating DC link 244 voltage amplitude variations by facilitating mitigation of a DC ripple sometimes associated with three-phase AC rectification.

The DC power is subsequently transmitted from DC link 244 to power converter 220 wherein converter 220 acts as an inverter configured to convert the DC electrical power transmitted from DC link 244 to a three-phase, sinusoidal AC electrical power with pre-determined voltages, currents, and frequencies. This conversion is monitored and controlled via controller 202. The converted AC power is transmitted from converter 220 to rotor filter 218 via bus 219 is subsequently transmitted to rotor 122 via bus 212. In this manner, generator reactive power control is facilitated.

Assembly 210 is configured to receive control signals from controller 202. The control signals are based on sensed conditions or operating characteristics of wind turbine 100 and system 200 as described herein and used to control the operation of the power conversion assembly 210. For example, tachometer 204 feedback in the form of sensed speed of the generator rotor 122 may be used to control the conversion of the output power from rotor bus 212 to maintain a proper and balanced three-phase power condition. Other feedback from other sensors also may be used by system 200 to control assembly 210 including, for example, stator and rotor bus voltages and current feedbacks. Using this feedback information, and for example, switching control signals, stator synchronizing switch control signals and system circuit breaker control (trip) signals may be generated in any known manner. For example, for a grid voltage transient with predetermined characteristics, controller 202 will at least temporarily substantially suspend firing of the IGBTs within converters 220, 222. 7KLV SURFHVV FDQ D0VR EH UHIHUUHG WR DV ³JDKQJ RII′ WRH, *%7V LQ FRQYHUWHUV 220, 222. Such suspension of operation of converters 220, 222 will substantially mitigate electric power being channeled through conversion assembly 210 to approximately zero.

Power converter assembly 210 and generator 118 may be susceptible to grid voltage fluctuations. Generator 118 may store magnetic energy that can be converted to high currents when a generator terminal voltage decreases quickly. Those currents can mitigate life expectancies of components of assembly 210 that may include, but not be limited to, semiconductor devices such as the IGBTs within converters 220 and 222. Similarly, during an islanding event, generator 118 becomes disconnected from the grid. This can result in an overvoltage on the electrical system 200 that connects the generation unit 118 with the grid. An overvoltage can be a short-term or longer duration increase in the measured voltage of the electrical system over its nominal rating. For example, the overvoltage may be 1%, 5% 10%, 50% or greater, and any values therebetween, of the measured voltage over the nominal voltage. This overvoltage on the AC side of line side converter 222 can causes energy to be pumped into capacitors 250, thereby increasing the voltage on the DC link 244. The higher voltage on the DC link 244 can damage one or more electronic switches such as a gate turn-off (GTO) thyristor, gate-commutated thyristor (GCT), insulated gate bipolar transistor (IGBT), MOSFET, combinations thereof, and the like located within the line side converter 222 and/or rotor converter 220.

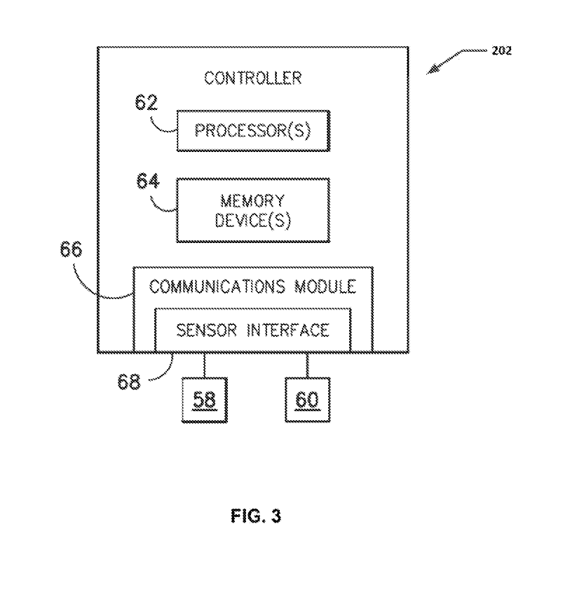

Referring now to FIG. 3, as noted above, some embodiments of systems for overvoltage protection can include a control system or controller 202. In general, the controller 202 may comprise a computer or other suitable processing unit. Thus, in several embodiments, the controller 202 may include suitable computer-readable instructions that, when implemented, configure the controller 202 to perform various different functions, such as receiving, transmitting and/or executing control signals. As such, the controller 202 may generally be configured to control the various operating modes (e.g., conducting or non-conducting states) of the one or more switches and/or components of embodiments of the electrical system 200. For example, the controller 200 may be configured to implement methods of detecting an islanding event of one or more electrical machines and taking actions to protect the one or more electrical machines during the islanding event.

FIG. 3 illustrates a block diagram of one embodiment of suitable components that may be included within an embodiment of a controller 202, or any other computing device that receives signals indicating islanding conditions in accordance with aspects of the present subject matter. In various aspects, such signals can be received from one or more sensors or transducers 58, 60, or may be received from other computing devices (not shown) such as a supervisory control and data acquisition (SCADA) system, a turbine protection system, PLL regulator 400 and the like. Received signals can include, for example, voltage signals such as DC bus 244 voltage and AC grid voltage along with corresponding phase angles for each phase of the AC grid, current signals, power flow (direction) signals, power output from the converter system 210, total power flow into (or out of) the grid, and the like. In some instances, signals received can be used by the controller 202 to calculate other variables such as changes in voltage phase angles over time, and the like. As shown, the controller 202 may include one or more processor(s) 62 and associated memory device(s) 64 configured to perform a variety of computer-implemented functions (e.g., performing the methods, steps, calculations and the like disclosed herein). As used KHUHLQ, WKH WHUP ³SURFHVVRU″ UHIHrs not only to integrated circuits referred to in the art as being included in a computer, but also refers to a controller, a microcontroller, a microcomputer, a programmable logic controller (PLC), an application specific integrated circuit, and other programmable circuits. Additionally, the memory device(s) 64 may generally comprise memory element(s) including, but not limited to, computer readable medium (e.g., random access memory (RAM)), computer readable non-volatile medium (e.g., a flash memory), a floppy disk, a compact disc-read only memory (CD-ROM), a magneto-optical disk (MOD), a digital versatile disc (DVD) and/or other suitable memory elements. Such memory device(s) 64 may generally be configured to store suitable computer-readable instructions that, when implemented by the processor(s) 62, configure the controller 202 to perform various functions including, but not limited to, directly or indirectly transmitting suitable control signals to one or more switches that comprise the bi-directional power conversion assembly 210, monitoring overvoltage and/or islanding conditions of the electrical system 200, and various other suitable computer-implemented functions.

Additionally, the controller 202 may also include a communications module 66 to facilitate communications between the controller 202 and the various components of the electrical system 200 and/or the one or more sources of electrical generation 118. For instance, the communications module 66 may serve as an interface to permit the controller 202 to transmit control signals to one or more switches that comprise the bi-directional power conversion assembly 210 to change to a conducting or non-conducting state. Moreover, the communications module 66 may include a sensor interface 68 (e.g., one or more analog-to-digital converters) to permit signals transmitted from the sensors (e.g., 58, 60) to be converted into signals that can be understood and processed by the processors 62. Alternatively, the controller 202 may be provided with suitable computer readable instructions that, when implemented by its processor(s) 62, configure the controller 202 to determine based on a first received indicator whether an islanding of the one or more sources of electrical generation 118 has occurred based on information stored within its memory 64 and/or based on an input received from the electrical system by the controller 202. Similarly, the controller 202 may be provided with suitable computer readable instructions that, when implemented by its processor(s) 62, configure the controller 202 to determine based on the one or more additional condition indicators whether an islanding of the one or more sources of electrical generation 118 has occurred based on information stored within its memory 64 and/or based on other inputs received from the electrical system 200 by the controller 202.

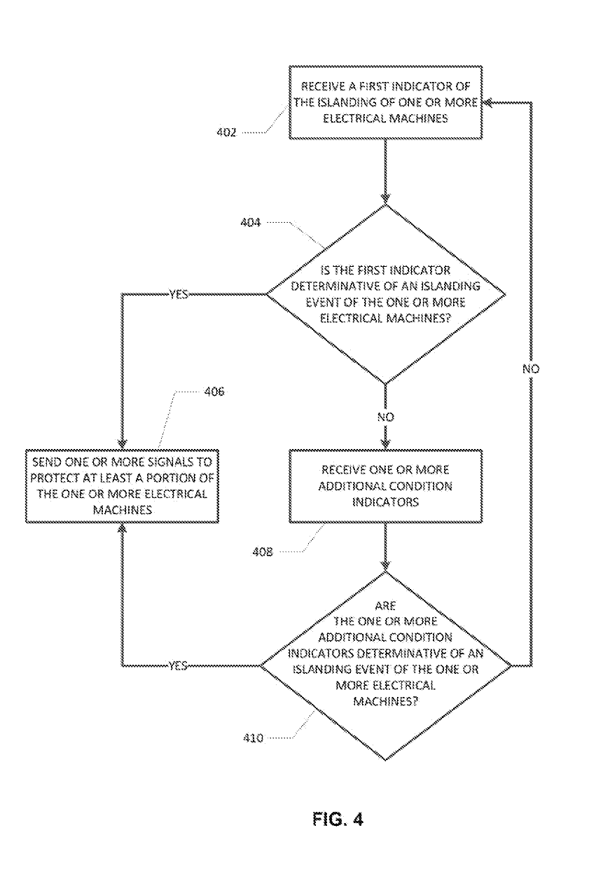

FIG. 4 is a flowchart illustrating an embodiment of a method of detecting islanding of one or more electrical machines such as wind turbine generators and protecting the one or more electrical machines during the islanding event. Embodiments of steps of the method described in FIG. 4 can be performed by one or more computing devices such as controller 202. As shown in FIG. 4, at step 402, a first indicator of an islanding of one or more electrical machines is received. Generally, this indicator is received by a computing device such as controller 202. In one aspect, this first indicator can be an indication of a voltage phase angle jump at, for example, the system bus 216 or the grid bus 242. The phase angle jump is a rapid change in the voltage phase angle of one or more phases of the AC voltage at, for example, the system bus 216 or the grid bus 242. Phase angle jump is determined by measuring real time phase angle displacement compared to its previous phase angle over a defined time period. If phase displacement error is higher than a threshold (in either positive or negative direction), a phase jump error can be declared. In one aspect, voltage phase angle is tracked, in real time, for one or more phases using the PLL regulator 400. A change in the tracked phase angle creates an output from the PLL regulator.

In another aspect, the first indicator can comprise an amplitude overvoltage at the system bus 216 or the grid bus 242 or even the DC bus 244. In another aspect, the first indicator of islanding can comprise a change in frequency on one or more phases of the system bus 216 or the grid bus 242. In particular, rapid changes in frequency may indicate islanding of the one or more electrical machines. In yet another aspect, the first indicator of islanding can include a signal from the AC grid circuit breaker 238 indicating the breaker has opened. In one aspect, upon receiving the first indicator of islanding, the controller can take steps to protect at least portions of the one or more electrical machines. For example, the controller can cause the machine and/or a convertor such as a line side converter to input reactive current into the electrical system in order to lower voltage. In other aspects, current commands can be given to the machine by the controller to cause real power produced by the machine to go to zero or nearly zero. While these are just a few examples, it is to be appreciated that the controller can cause steps to be taken to lower the voltage RQ WKH H0HWULFD0 V\VWHP WKDW¶v EHLQJ H[SHULHQFHG E\ WKH RQH RU PRUH PDFKLQHV DQG/RU to demagnetize and reduce or halt the production of real power by the machine as quickly as possible.

At step 404, the computing device can make a determination whether the received first indicator is determinative of islanding of the one or more electrical machines. In this sense, determinative, as used herein, means that the one or more electrical machines are more likely than not experiencing an islanding event. For example, thresholds may be established for the first indicator. As an example, the computing device can make a determination that the received first indicator is determinative of islanding of the one or more electrical machines and to immediately take action to protect at least a portion of the one or more electrical machines if the voltage phase angle jump exceeds approximately plus or minus 30 degrees. In another aspect, if the voltage phase angle jump does not exceed approximately plus or minus 30 degrees, but an overvoltage of 125% or greater is detected at the system bus 216 or the grid bus 242 or even the DC bus 244, then the computing device can make a determination that the received first indicator is determinative of islanding of the one or more electrical machines and to immediately take action to protect at least a portion of the one or more electrical machines. It is to be appreciated that these thresholds are exemplary only and can be adjusted as desired in order to protect at least a portion of the one or more electrical machines, any other values for such thresholds are contemplated within the scope of embodiments of the present invention. At step 406, in one aspect, if the first indicator is determinative of islanding of the one or more electrical machines, then the computing device can take action to protect at least a portion of the one or more electrical machines by the computing device sending one or more signals to portions of the one or more electrical machines or portions of the electrical system 200. For example, the computing device can take action to protect at least a portion of the one or more electrical machines by sending one or more signals to one or more switches that comprise at least a portion of the one or more electrical machines to place the switches in a non-conducting state. For example, these switches may comprise electronic switches in the rotor-side, bi-directional power converter 220 and/or the line-side, bi-directional power converter 222. For example, these switches may comprise one or more insulated gate bipolar transistors (IGBTs), gate turn-off (GTO) thyristors, gate-commutated thyristors (GCT), MOSFET, combinations thereof, and the like. By placing these switches in a non-conducting state, the rotor-side, bi-directional power converter 220, the line-side, bi-directional power converter 222 and the one or more electrical machines can be protected from overvoltages and transients caused by islanding of the one or more electrical machines. In another example, the computing device may send protection trip or shutdown signals to one or more components that comprise the one or more electrical machines.

Though not shown in FIG. 4, in one aspect, after making a determination that the first indicator is determinative of islanding of the one or more electrical machines, a delay can be introduced to the process. This delay can cause the computing device to receive additional indicators to further verify the islan ding event or to make a determination that islanding has not occurred. For example, if the monitored electrical system returns to normal operation after a short time period, then the computing device may send one or more signals such that one or more switches that comprise at least a portion of the one or more electrical machines are placed back in a conducting state. Alternatively, if the islanding event is confirmed, then the switches remain in the non-conducting state.

Returning to step 404, if the computing device can make a determination that the received first indicator is not determinative of islanding of the one or more electrical machines, then at step 408 one or more additional condition indicators are received by the computing device. These one or more additional condition indicators can be, for example, one or more of an indication of an overvoltage on an alternating current (AC) electric power system 200 connected to the one or more electrical machines, an indication of an overvoltage on the DC bus 244, an indication of reverse power flow through the line side converter 222, an indication of an excessive magnitude of power flow through the line side convertor 222 or the rotor convertor 220, and the like. In one aspect, at step 410, the first indicator in combination with the one or more additional indicators can be used by the computing device to make a determination whether to take action to protect at least a portion of the one or more electrical machines. For example, the voltage phase angle jump in combination with at least one of an indication of an overvoltage on an alternating current (AC) electric power system connected to the one or more electrical machines, an indication of an overvoltage on the DC bus, an indication of reverse power flow through the line side converter, an indication of a magnitude of power flow through the line side convertor or the rotor convertor and the like can be used by the computing device to determine whether to take action to protect at least a portion of the one or more electrical machines. Consider one non-limiting example, if the voltage phase angle jump is less than or equal to approximately 30 degrees or equal to or greater than negative 30 degrees and the indication of the overvoltage on an alternating current (AC) electric power system connected to the one or more electrical machines indicates the overvoltage is approximately 125 percent or greater than nominal voltage, then the computing device sends one or more signals such that one or more switches that comprise at least a portion of the one or more electrical machines are placed in a non-conducting state.

Also at step 410, in another aspect, if any combination of the additional one or more condition indicators are determinative of islanding of the one or more electrical machines, then the computing device can take action to protect the one or more electrical machines. For example, one or more of an indication of an overvoltage on an alternating current (AC) electric power system connected to the one or more electrical machines, an overvoltage on the DC bus, an indication of reverse power flow through the line side converter, an indication of a magnitude of power flow through the line side convertor or the rotor convertor, power flow into the grid, and the like, in any combination, can be used by the computing device to determine whether to take action to protect at least a portion of the one or more electrical machines.

Consider the following non-limiting example, where an electrical machine has a threshold of 1100 volts (DC) or greater as an indication for DC bus overvoltage, 115 percent of nominal or greater as a threshold for an indication of an overvoltage on an alternating current (AC) electric power system connected to the one or more electrical machine, negative 300 (−300) kilowatts (kW) or greater (e.g., −350 kW) as a threshold for an indication of reverse power flow through the line side converter or the rotor convertor and a threshold of 100 kW or less for power flow into the grid. If these thresholds are met for each of the above-identified additional one or more condition indicators, then the computing device will take action to gate off the switches of the line side convertor 222 and/or the rotor-side convertor 220 to protect the one or more electrical machines.

If, at step 410, the computing device determines that the one or more additional condition indicators in combination with the first indicator are not determinative of islanding of the one or more electrical machines and, then at the process returns to step 402, as described above. Otherwise, if at step 410 the computing device determines to take action to protect at least a portion of the one or more electrical machines based on the one or more additional condition indicators or the one or more additional condition indicators in combination with the first indicator, then at the process goes to step 406, as described above.

As described above and as will be appreciated by one skilled in the art, embodiments of the present invention may be configured as a system, method, or a computer program product. Accordingly, embodiments of the present invention may be comprised of various means including entirely of hardware, entirely of software, or any combination of software and hardware. Furthermore, embodiments of the present invention may take the form of a computer program product on a computer-readable storage medium having computer-readable program instructions (e.g., computer software) embodied in the storage medium. Any suitable non-transitory computer-readable storage medium may be utilized including hard disks, CD-ROMs, optical storage devices, or magnetic storage devices.

Embodiments of the present invention have been described above with reference to block diagrams and flowchart illustrations of methods, apparatuses (i.e., systems) and computer program products. It will be understood that each block of the block diagrams and flowchart illustrations, and combinations of blocks in the block diagrams and flowchart illustrations, respectively, can be implemented by various means including computer program instructions. These computer program instructions may be loaded onto a general purpose computer, special purpose computer, or other programmable data processing apparatus, such as the processor(s) 62 discussed above with reference to FIG. 3, to produce a machine, such that the instructions which execute on the computer or other programmable data processing apparatus create a means for implementing the functions specified in the flowchart block or blocks.

These computer program instructions may also be stored in a non-transitory computer-readable memory that can direct a computer or other programmable data processing apparatus (e.g., processor(s) 62 of FIG. 3) to function in a particular manner, such that the instructions stored in the computer-readable memory produce an article of manufacture including computer-readable instructions for implementing the function specified in the flowchart block or blocks. The computer program instructions may also be loaded onto a computer or other programmable data processing apparatus to cause a series of operational steps to be performed on the computer or other programmable apparatus to produce a computer-implemented process such that the instructions that execute on the computer or other programmable apparatus provide steps for implementing the functions specified in the flowchart block or blocks.

Accordingly, blocks of the block diagrams and flowchart illustrations support combinations of means for performing the specified functions, combinations of steps for performing the specified functions and program instruction means for performing the specified functions. It will also be understood that each block of the block diagrams and flowchart illustrations, and combinations of blocks in the block diagrams and flowchart illustrations, can be implemented by special purpose hardware-based computer systems that perform the specified functions or steps, or combinations of special purpose hardware and computer instructions.

Unless otherwise expressly stated, it is in no way intended that any method set forth herein be construed as requiring that its steps be performed in a specific order. Accordingly, where a method claim does not actually recite an order to be followed by its steps or it is not otherwise specifically stated in the claims or descriptions that the steps are to be limited to a specific order, it is no way intended that an order be inferred, in any respect. This holds for any possible non-express basis for interpretation, including: matters of logic with respect to arrangement of steps or operational flow; plain meaning derived from grammatical organization or punctuation; the number or type of embodiments described in the specification.

Throughout this application, various publications may be referenced. The disclosures of these publications in their entireties are hereby incorporated by reference into this application in order to more fully describe the state of the art to which the methods and systems pertain.

Many modifications and other embodiments of the inventions set forth herein will come to mind to one skilled in the art to which these embodiments of the invention pertain having the benefit of the teachings presented in the foregoing descriptions and the associated drawings. Therefore, it is to be understood that the embodiments of the invention are not to be limited to the specific embodiments disclosed and that modifications and other embodiments are intended to be included within the scope of the appended claims. Moreover, although the foregoing descriptions and the associated drawings describe exemplary embodiments in the context of certain exemplary combinations of elements and/or functions, it should be appreciated that different combinations of elements and/or functions may be provided by alternative embodiments without departing from the scope of the appended claims. In this regard, for example, different combinations of elements and/or functions than those explicitly described above are also contemplated as may be set forth in some of the appended claims. Although specific terms are employed herein, they are used in a generic and descriptive sense only and not for purposes of limitation.

What is claimed is:

1. A method of protecting one or more electrical machines during an islanding event, said method comprising:
(a) receiving a first indicator of an islanding of one or more electrical machines;
(b) determining, by a computing device, whether the received first indicator is determinative of islanding of the one or more electrical machines;
(c) if the computing device determines that the received first indicator is determinative of islanding of the one or more electrical machines, then sending one or more signals by the computing device to protect the one or more electrical machines;
(d) if the computing device determines that the received first indicator is not determinative of islanding of the one or more electrical machines, then receiving one or more additional condition indicators;
(e) determining, by the computing device, whether the one or more additional condition indicators are determinative of islanding of the one or more electrical machines;
(f) if the computing device determines that the one or more additional condition indicators are determinative of islanding of the one or more electrical machines, then sending the one or more signals by the computing device to protect at least a portion of the one or more electrical machines; and
(g) if the computing device determines that the one or more additional condition indicators and not determinative of islanding of the one or more electrical machines, then repeating steps (a) through (g).

2. The method of claim 1, wherein receiving the first indicator of the islanding of one or more electrical machines comprises receiving the first indicator of the islanding of one or more wind turbine generators.

3. The method of claim 1, wherein receiving the first indicator of islanding of the one or more electrical machines further comprises the computing device taking steps to protect at least portions of the one or more electrical machines in response to the received first indicator of islanding.

4. The method of claim 1, wherein receiving the first indicator of the islanding of one or more electrical machines comprises receiving at least one of an indication of a voltage phase angle jump on an alternating current (AC) electric power system that is operably connected with the one or more electrical machines, an indication of an opening of a breaker that electrically connects the AC electrical power system with an electrical grid, an indication of an AC amplitude overvoltage on the AC electrical power system, or an indication of rapid frequency shifting on the AC electrical power system.

5. The method of claim 4, wherein determining, by the computing device, whether the received first indicator is determinative of islanding of the one or more electrical machines comprises taking action to protect at least a portion of the one or more electrical machines if the first indicator exceeds a threshold value for the first indicator.

6. The method of claim 5, wherein the first indicator is the voltage phase angle jump and the threshold value for voltage phase angle jump comprises approximately plus or minus 30 degrees.

7. The method of claim 5, wherein if the first indicator exceeds a threshold value for the first indicator, then sending one or more signals by the computing device to protect at least a portion of the one or more electrical machines comprises the computing device sending one or more signals such that one or more switches that comprise at least a portion of the one or more electrical machines are placed in a non-conducting state.

8. The method of claim 6, further comprising determining, by the computing device, that the first indicator is not determinative of an islanding of the one or more electric machines and the computing device sending one or more signals such that one or more switches that comprise at least a portion of the one or more electrical machines are placed in a conducting state.

9. The method of claim 3, wherein the one or more electrical machines are electrically connected with an electric grid and the one or more electrical machines are further comprised of at least a line side converter, a direct current (DC) bus and a rotor converter and wherein if the computing device determines that the received first indicator is not determinative of islanding of the one or more electrical machines, then receiving one or more additional condition indicators comprises receiving one or more additional indicators comprised of one or more of an indication of an overvoltage on an alternating current (AC) electric power system connected to the one or more electrical machines, an indication of an overvoltage on the DC bus, an indication of reverse power flow through the line side converter, an indication of a magnitude of power flow through the line side convertor or the rotor convertor, and an indication of power flow into the electrical grid.

10. The method of claim 9, wherein the first indicator in combination with at least one of the additional condition indicators are used by the computing device to determine whether to take action to protect at least a portion of the one or more electrical machines.

11. The method of claim 10, wherein the first indicator is the voltage phase angle jump and if the voltage phase angle jump is less than or equal to approximately 30 degrees or equal to or greater than negative 30 degrees and the indication of the overvoltage on an alternating current (AC) electric power system connected to the one or more electrical machines indicates the overvoltage is approximately 125 percent or greater than nominal voltage, then the computing device sending one or more signals such that one or more switches that comprise at least a portion of the one or more electrical machines are placed in a non-conducting state.

12. The method of claim 9, wherein one or more of an indication of an overvoltage on an alternating current (AC) electric power system connected to the one or more electrical machines, an indication of an overvoltage on the DC bus, an indication of reverse power flow through the line side converter, an indication of a magnitude of power flow through the line side convertor or the rotor convertor or an indication of power flow into the electrical grid, in any combination, are used by the computing device to determine whether to take action to protect at least a portion of the one or more electrical machines.

13. The method of claim 1, wherein if the computing device determines that the received first indicator is determinative of islanding of the one or more electrical machines, then sending one or more signals by the computing device to protect the one or more electrical machines comprises sending one or more signals such that one or more switches that comprise at least a portion of the one or more electrical machines are placed in a non-conducting state.

14. The method of claim 13, further comprising determining, by the computing device, that the first indicator is not determinative of islanding of the one or more electric machines and the computing device sending one or more signals such that one or more switches that comprise at least a portion of the one or more electrical machines are placed in a conducting state.

15. The method of claim 1, wherein if the computing device determines that the one or more additional condition indicators are determinative of islanding of the one or more electrical machines, then sending one or more signals by the computing device to protect the one or more electrical machines comprises sending one or more signals such that one or more switches that comprise at least a portion of the one or more electrical machines are placed in a non-conducting state.

16. The method of claim 15, further comprising determining, by the computing device, that the one or more additional condition indicators are not determinative of an islanding of the one or more electric machines and the computing device sending one or more signals such that one or more switches that comprise at least a portion of the one or more electrical machines are placed in a conducting state.

17. A method of protecting one or more electrical machines during an islanding event, said method comprising:
connecting one or more electrical machines to an alternating current (AC) electric power system, wherein the AC electric power system is configured to transmit at least one phase of electrical power to the one or more electrical machines or to receive at least on phase of electrical power from the one or more electrical machines;
electrically coupling at least a portion of a control system to at least a portion of the AC electric power system;
coupling at least a portion of the control system in electronic data communication with at least a portion of the one or more electrical machines; and
detecting an islanding of the one or more electrical machines based on one or more conditions monitored by the control system, said detecting comprising:
(a) receiving a first indicator of an islanding of the one or more electrical machines;
(b) determining, by the control system, whether said received first indicator is determinative of islanding;
(c) if the control system determines that the received first indicator is determinative of islanding, then sending one or more signals by the control system to protect the one or more electrical machines;
(d) if the control system determines that the received first indicator is not determinative of islanding, then receiving one or more additional condition indicators;
(e) determining, by the control system, whether the one or more additional condition indicators are determinative of islanding; and
(f) if the control system determines that the one or more additional condition indicators are determinative of islanding, then sending the one or more signals by the control system to protect at least a portion of the one or more electrical machines.

18. The method of claim 17 further comprising configuring the one or more electrical machines and the control system such that one or more switches that comprise at least a portion of the one or more electrical machines are placed in a non-conducting state when the one or more conditions monitored by the control system are determinative of the islanding of the one or more electrical machines.

19. A system for detecting an islanding event of one or more electrical machines and protecting the one or more electrical machines, said system comprising:
one or more electrical machines connected to an alternating current (AC) electric power system, wherein the AC electric power system is configured to transmit at least one phase of electrical power to the one or more electrical machines or to receive at least on phase of electrical power from the one or more electrical machines;
a control system, wherein the control system is electrically coupled to at least a portion of the AC electric power system and at least a portion of the control system is coupled in electronic data communication with at least a portion of the one or more electrical machines, and wherein said control system comprises a controller and said controller is configured to:
(a) receive a first indicator of an islanding of the one or more electrical machines;
(b) determine whether the received first indicator is determinative of islanding of the one or more electrical machines;
(c) if the controller determines that the received first indicator is determinative of islanding of the one or more electrical machines, then sending one or more signals to protect the one or more electrical machines;
(d) if the controller determines that the received first indicator is not determinative of islanding of the one or more electrical machines, then receiving one or more additional condition indicators;
(e) determine whether the one or more additional condition indicators are determinative of islanding of the one or more electrical machines;
(f) if the controller determines to that the one or more additional condition indicators are determinative of islanding of the one or more electrical machines, then sending the one or more signals to protect at least a portion of the one or more electrical machines; and
(g) if the controller determines that the one or more additional condition indicators are not determinative of islanding of the one or more electrical machines, then repeating steps (a) through (g).

20. The system of claim 19, wherein the one or more electrical machines comprise one or more wind turbine generators.
